(19) United States
(12) Patent Application Publication
(10) Pub. No.: US 2007/0296000 A1
(43) Pub. Date: Dec. 27, 2007

(54) Method for manufacturing a semiconductor device

(75) Inventor: Toshiki Hara, Suwa-shi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/818,688

(22) Filed: Jun. 15, 2007

(30) Foreign Application Priority Data
Jun. 21, 2006 (JP) 2006-171356
Jan. 18, 2007 (JP) 2007-008741

(51) Int. Cl. H01L 27/10; H01L 29/74

(52) U.S. Cl. 257/211

(57) ABSTRACT

A method for manufacturing a semiconductor device, includes: partially forming an epitaxial growth stopper film on a single crystal semiconductor substrate; sequentially depositing a first semiconductor layer and a second semiconductor layer on the semiconductor substrate by an epitaxial growth process; forming a first groove penetrating through the second semiconductor layer and the first semiconductor layer on the semiconductor substrate, at a region inside from an outer peripheral portion of the epitaxial growth stopper film, by partially etching the second semiconductor layer and the first semiconductor layer; forming a support body film on an entire surface of the semiconductor substrate, so as to fill the first groove and cover the second semiconductor layer; forming a support body in a shape covering the second semiconductor layer from the first groove to an element region extending over the outer peripheral portion of the epitaxial growth stopper film, by partially etching the support body film; forming a second groove exposing a side surface of the first semiconductor layer, by sequentially etching the second semiconductor layer and the first semiconductor layer exposing from under the support body; forming a hollow portion between the semiconductor substrate and the second semiconductor layer, by selectively etching the first semiconductor layer interposing the second groove therebetween, under an etching condition that the first semiconductor layer is easier to etch than the second semiconductor layer; and forming an insulating layer in the hollow portion.

### BACKGROUND

1. Technical Field

Several aspectrs of the present invention relate to a method for manufacturing a semiconductor device. More particularly, the present invention relates to a technology for forming a silicon-on-insulator (SOI) structure on a semiconductor substrate.

2. Related Art

A field-effect transistor formed on an SOI substrate has attracted attention for its usefulness, in terms of easy element isolation, a latch-up free, and a small source and drain junction capacitance. A method for forming an SOI structure on a bulk wafer, for example, is to grow a silicon germanium (SiGe) layer and a silicon (Si) layer on a substrate by epitaxial growth, and a first groove having a depth deeper than a bottom surface of the SiGe layer is formed thereto. A silicon oxide (SiO₂) film as a support body film is formed by a chemical vapor deposition (CVD) method, so as to fill the first groove. A support body is formed by dry etching the support body film into a shape of an element region, and the Si layer and the SiGe layer are also dry etched successively. By successively dry etching the Si layer and the SiGe layer exposing from under the support body, a second groove is formed on the substrate.

Next, when the SiGe layer is etched by fluoronitric acid (mixture of fluoric acid and nitric acid) interposing the second groove therebetween, a hollow portion is formed under the Si layer in a shape that the Si layer is hanging down from the support body. Then, by filling the hollow portion with the SiO₂ film (the SiO₂ film may be referred to as a “BOX”) using a thermal oxidation, for example, it becomes the SOI structure. Such a process is called a separation by bonding Si islands (SBSI) process, and for example, disclosed in JP-A-2005-354024 and a non-patent literature, T. Sakai et al., “Separation by Bonding Si Islands (SBSI) for LSI Application”, Second International SiGe Technology and Device Meeting, Meeting Abstract, pp. 230-231, May 2004.

In the SBSI process, a shape of the SOI structure formed on the bulk wafer is usually rectangular in a plan view. And as shown in FIG. 9, in the SBSI process of the related art, a BOX (SiO₂ film) 131 is formed on an undersurface of a Si layer 113, in a state that an upper surface of the Si layer 113 and two surfaces out of four side surfaces of the Si layer 113 facing each other, are in contact with a support body (SiO₂ film) 122. In other words, the upper surface and the side surfaces of the Si layer 113 are in contact with the support body 122, and its undersurface is in contact with the BOX 131, during a thermal oxidation for forming the BOX (hereinafter, referred to as a “BOX forming oxidation”).

As coefficients of thermal expansion between Si and SiO₂ are different, SiO₂ is dissolved slightly to be irreversibly deformed by heat treatment. Also, when the composition changes from Si to SiO₂ by the thermal oxidation, its volume expands by almost doubling its size. Further, while the support body 122 is formed by the CVD, the BOX 131 is formed by the thermal oxidation. Therefore, although they are made of the same SiO₂ film, the support body 122 and the BOX 131 have different characteristics.

For these reasons, external forces are applied to the Si layer 113 in a complicated manner from a plurality of directions during the BOX forming oxidation. And there was a possibility of causing a large stress to the Si layer 113 by the effect. The stress applied to the Si layer 113 affects transistor characteristics (especially, mobility). As a magnitude of the stress is often not uniform in a wafer surface, there was a problem that the transistor characteristics tend to vary in the wafer surface.

### SUMMARY

An advantage of the invention is to provide a method for manufacturing a semiconductor device having an SOI structure which can obtain desired transistor characteristics.

As a first aspect of the invention, a method for manufacturing a semiconductor device includes: partially forming an epitaxial growth stopper film on a single crystal semiconductor substrate; sequentially depositing a first semiconductor layer and a second semiconductor layer on the semiconductor substrate by an epitaxial growth process, and forming a first groove penetrating through the second semiconductor layer and the first semiconductor layer on the semiconductor substrate, at a region inside from an outer peripheral portion of the epitaxial growth stopper film, by partially etching the second semiconductor layer and the first semiconductor layer. The first aspect also includes forming a support body film on an entire surface of the semiconductor substrate, so as to fill the first groove and cover the second semiconductor layer, and a step of forming a support body in a shape covering the second semiconductor layer from the first groove to an element region, extending over the outer peripheral portion of the epitaxial growth stopper film, by partially etching the support body film. The first aspect further includes forming a second groove exposing a side surface of the first semiconductor layer, by sequentially etching the second semiconductor layer and the first semiconductor layer exposing from under the support body, forming a hollow portion between the semiconductor substrate and the second semiconductor layer, by selectively etching the first semiconductor layer interposing the second groove therebetween, under an etching condition that the first semiconductor layer is easier to etch than the second semiconductor layer, and forming an insulating layer in the hollow portion.

In the first aspect, the “epitaxial growth stopper film”, for example, is a film having an amorphous structure. When the first semiconductor layer and the second semiconductor layer are formed by the epitaxial growth process, a portion directly formed on the semiconductor substrate becomes a single crystal structure, but a portion formed on the epitaxial growth stopper film becomes a polycrystalline structure or the amorphous structure, in the first semiconductor layer and the second semiconductor layer. In a case when the semiconductor substrate, for example, is a single crystal silicon substrate, the first semiconductor layer, for example, is silicon germanium (SiGe), and the second semiconductor layer, for example, is silicon (Si), a silicon oxide (SiO₂) film, for example, may be used as the epitaxial growth stopper film.

Also, the “element region” is a region where the SOI structure (in other words, a structure that a semiconductor layer exists on an insulating layer) is formed. To the semiconductor layer at an upper portion of the SOI structure (in other words, the second semiconductor layer), an element such as a transistor, for example, is formed.

According to the first aspect, a portion which comes into contact with the support body (hereinafter, referred to as a “support body adjacent portion”) in the second semiconductor layer may be formed in the polycrystalline structure or the amorphous structure. Therefore, when the hollow portion is formed between the semiconductor substrate and the second semiconductor layer, not only the first semiconductor layer, but also the support body adjacent portion in the second semiconductor layer can be etched, thereby enabling to provide a space between the side surface of the second semiconductor layer and the support body. When the insulating layer is formed in the hollow portion, the stress of the second semiconductor layer can be relieved, as the side surface of the second semiconductor layer is separated from the support body. Therefore, desired transistor characteristics can be obtained.

As a second aspect of the invention, a method for manufacturing a semiconductor device includes sequentially depositing a first semiconductor layer and a second semiconductor layer on a single crystal semiconductor substrate by an epitaxial growth process, forming a first groove penetrating through the second semiconductor layer and the first semiconductor layer on the semiconductor substrate, by partially etching the second semiconductor layer and the first semiconductor layer, and forming a support body film on an entire surface of the semiconductor substrate, so as to fill the first groove and cover the second semiconductor layer. The second aspect also includes forming a support body in a shape covering the second semiconductor layer from the first groove to an element region, by partially etching the support body film, and forming a second groove exposing a side surface of the first semiconductor layer, by sequentially etching the second semiconductor layer and the first semiconductor layer exposing from under the support body. The second aspect further includes a step of forming a hollow portion between the semiconductor substrate and the second semiconductor layer, by selectively etching the first semiconductor layer interposing the second groove therebetween, under an etching condition that the first semiconductor layer is easier to etch than the second semiconductor layer, forming an insulating layer in the hollow portion, and forming an epitaxial growth stopper film on the semiconductor substrate at a region sandwiched between a region forming the first groove and the element region before forming the first semiconductor layer, and the first semiconductor layer and the second semiconductor layer are also deposited on the epitaxial growth stopper film in the step of forming the first semiconductor layer and the second semiconductor layer.

According to the second aspect of the invention , the support body adjacent portion in the second semiconductor layer can be formed into the polycrystalline structure or the amorphous structure. Therefore, when the hollow portion is formed between the semiconductor substrate and the second semiconductor layer, not only the first semiconductor layer but also the support body adjacent portion of the second semiconductor layer can be etched, thereby enabling to provide a space between the side surface of the second semiconductor layer and the support body. When the insulating layer is formed in the hollow portion, the stress of the second semiconductor layer can be relieved, as the side surface of the second semiconductor layer is separated from the support body. Therefore, the desired transistor characteristics can be obtained.

As a third aspect of the invention, a method for manufacturing a semiconductor device according to the first and second aspects of the method for manufacturing the semiconductor device includes that the epitaxial growth stopper film is an element isolation layer. In the third aspect, the “element isolation layer”, for example, is formed by a local oxidation of silicon (LOCOS) process. According to the third aspect, forming the epitaxial growth stopper film and forming element isolation can be performed at the same time, thereby enabling to reduce the number of manufacturing steps.

### BRIEF DESCRIPTION OF THE DRAWINGS

The invention will be described with reference to the accompanying drawings, wherein like numbers reference like elements.

FIGS. 1A and 1B are diagrams showing a method for manufacturing a semiconductor device according to a first embodiment (first step).

FIGS. 2A and 2B are diagrams showing the method for manufacturing the semiconductor device according to the first embodiment (second step).

FIGS. 3A and 3B are diagrams showing the method for manufacturing the semiconductor device according to the first embodiment (third step).

FIGS. 4A and 4B are diagrams showing the method for manufacturing the semiconductor device according to the first embodiment (fourth step).

FIGS. 5A and 5B are diagrams showing the method for manufacturing the semiconductor device according to the first embodiment (fifth step).

FIGS. 6A and 6B are diagrams showing the method for manufacturing the semiconductor device according to the first embodiment (sixth step).

FIGS. 7A through 7C are diagrams showing the method for manufacturing the semiconductor device according to the first embodiment (seventh step).

FIGS. 8A through 8D are diagrams showing a method for manufacturing a semiconductor device according to a second embodiment.

FIG. 9 is a diagram showing a problem of a related art.

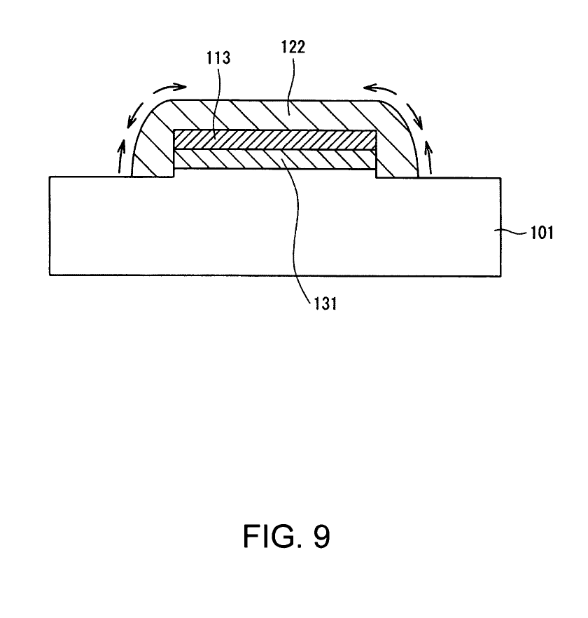

### DESCRIPTION OF EXEMPLARY EMBODIMENTS

Embodiments of the invention will now be described with reference to the accompanying drawings.

### First Embodiment

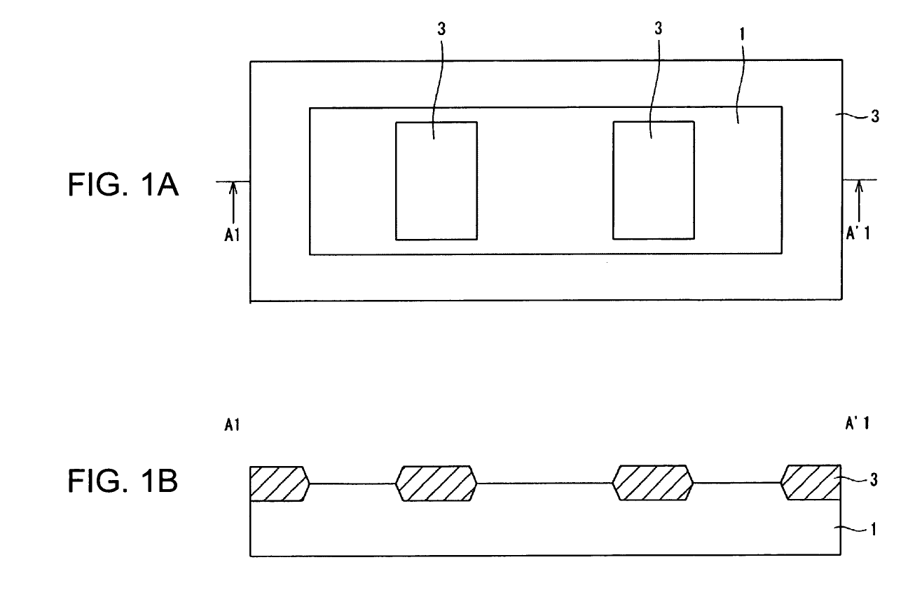

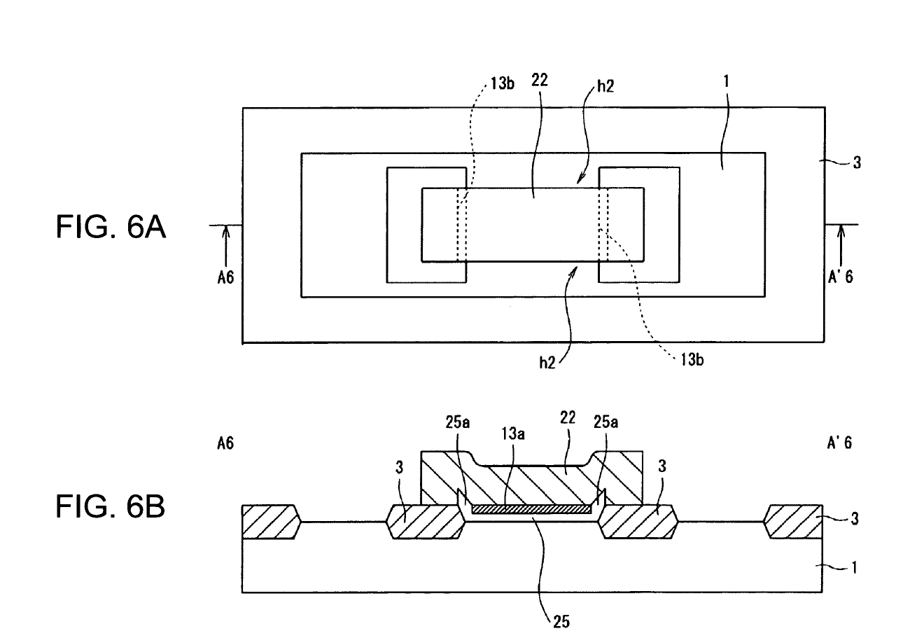

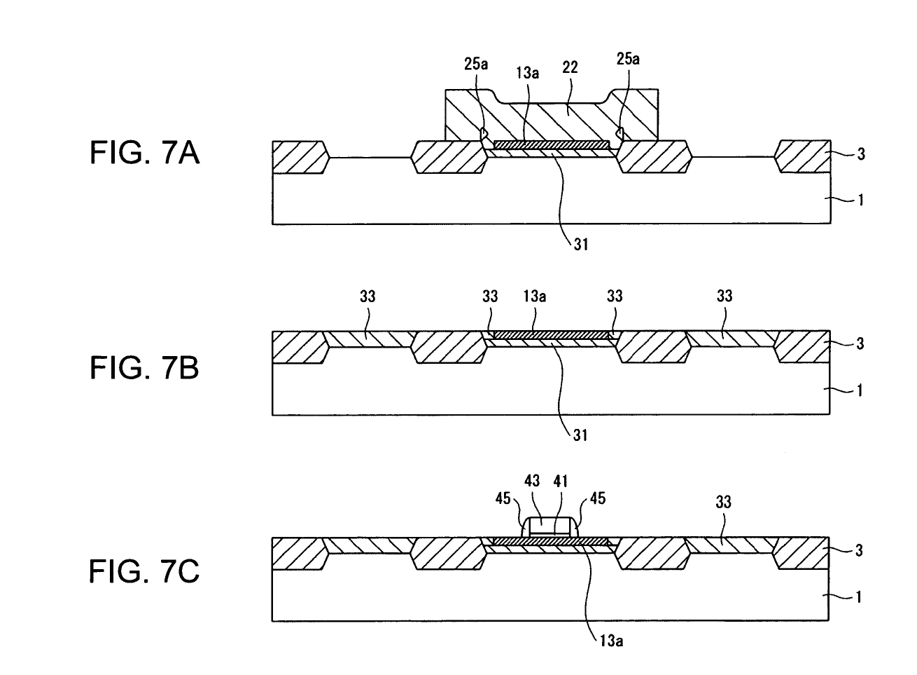

FIGS. 1A through 7C are diagrams showing a method for manufacturing a semiconductor device according to a first embodiment of the present invention. FIGS. 1A through 6A are plan views. FIGS. 1B through 6B are sectional views taken along the lines A1-A1′ to A6-A′6 of FIGS. 1A through 6A, respectively. FIGS. 7A through 7C are sectional views showing manufacturing steps following the step shown in FIG. 6B.

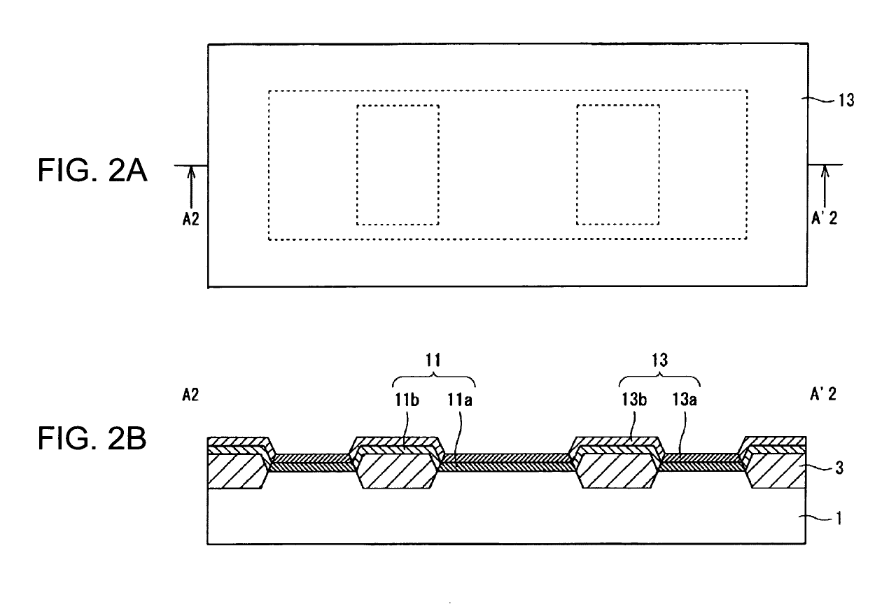

As shown in FIGS. 1A and 1B, an element isolation layer 3 is formed on a single crystal silicon (Si) substrate 1 using a LOCOS process. Next, in FIGS. 2A and 2B, a silicon buffer (Si-buffer) layer, which is not shown, is formed on the Si substrate 1. Silicon germanium (SiGe) layers 11a and 11b are formed thereon, and silicon (Si) layers 13a and 13b are formed thereon. The Si-buffer layer, the SiGe layers 11a and 11b, and the Si layers 13a and 13b, for example, are formed by an epitaxial growth process.

In the epitaxial growth process, a crystal structure of a film deposition surface of an underlying member reflects a crystal structure of a film grown on the underlying member. In other words, a film having a single crystal structure is formed on the single crystal structure, and a film having a polycrystalline structure or an amorphous structure is formed on the polycrystalline structure or the amorphous structure. Therefore, as shown in FIG. 2B, the single crystal SiGe layer 11a is formed on the single crystal Si substrate 1, and the SiGe layer 11b having the polycrystalline structure or the amorphous structure is formed on the element isolation layer 3 having the amorphous structure. And the single crystal Si layer 13a is formed on the single crystal SiGe layer 11a, and the SiGe layer 13b having the polycrystalline structure or the amorphous structure is formed on the SiGe layer 11b having the polycrystalline structure or the amorphous structure.

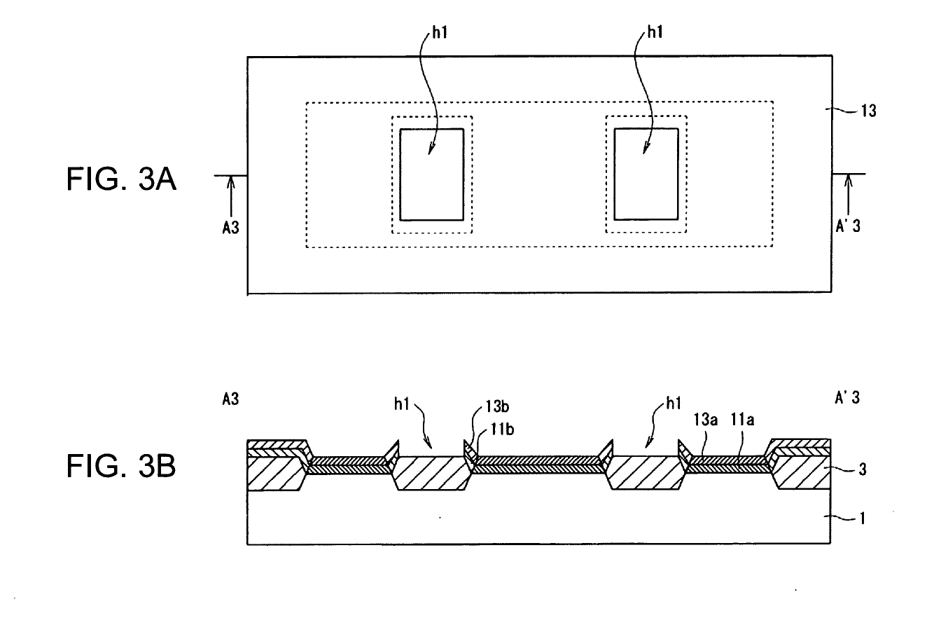

The thickness of the SiGe layers 11a and 11b, and the Si layers 13a and 13b, for example, are approximately 1 to 200 nm. In FIGS. 2A and 3A, the single crystal Si layer 13a and the Si layer 13b having the polycrystalline structure or the amorphous structure are collectively referred to as a Si layer 13, for illustrative purposes.

Next, as shown in FIGS. 3A and 3B, the Si layer 13b, the SiGe layer 11b and the Si-buffer layer (not shown) are partially etched, by using a photolithography technique and an etching technique. This allows to form a support body hole h1 penetrating through the Si layer 13b, the SiGe layer 11b and the Si-buffer layer, and having the element isolation layer 3 as a bottom surface, at a region inside from an outer peripheral portion (in other words, at a bird's beak) of the element isolation layer 3. In an etching step forming the support body hole h1, the etching may be stopped at a surface of the element isolation layer 3, or a recess may be formed at a region other than the bird's beak, by over etching the element isolation layer 3.

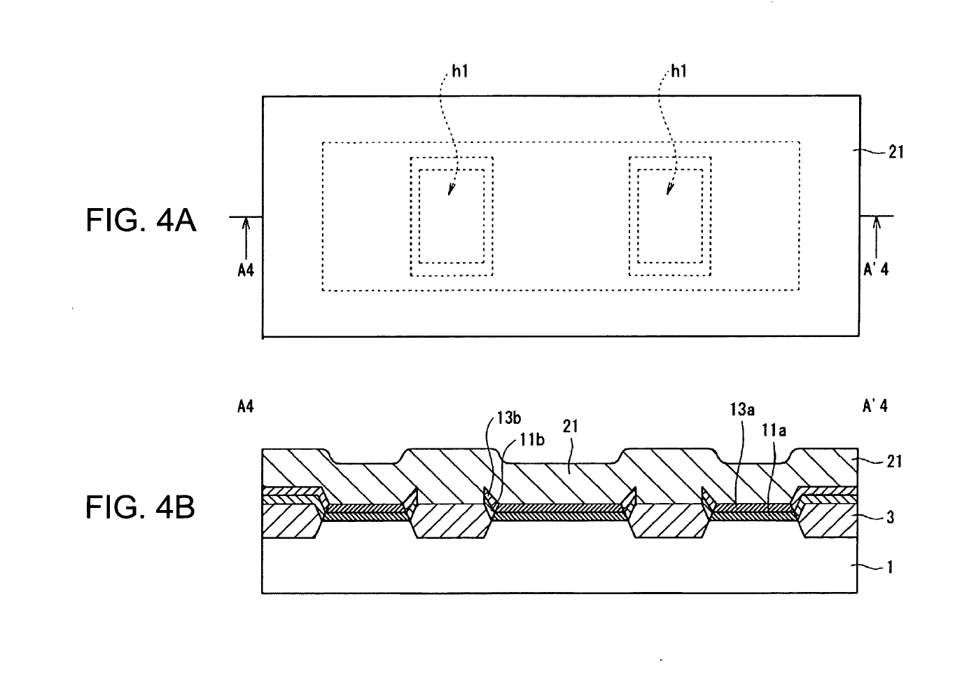

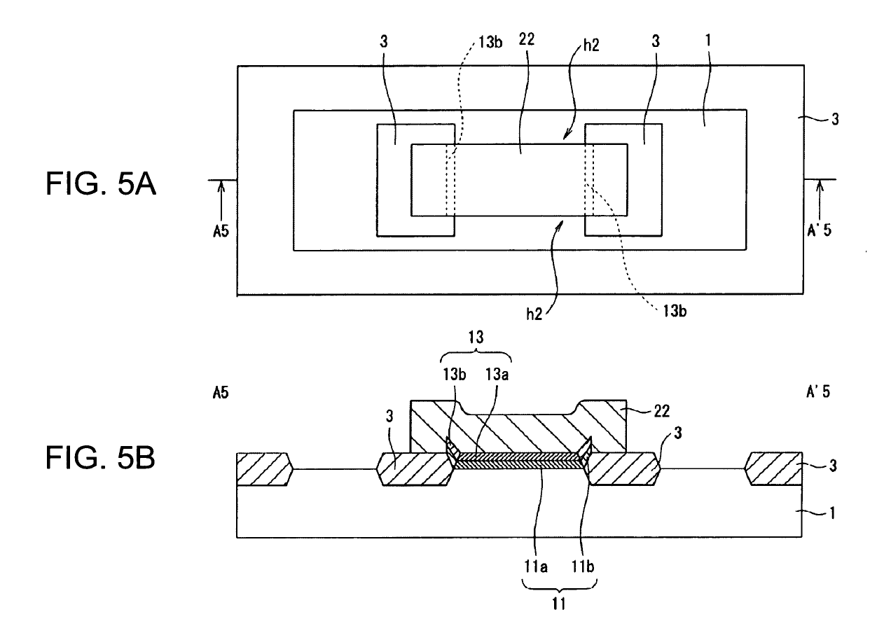

Next, as shown in FIGS. 4A and 4B, a support body film 21 is formed on an entire surface of the Si substrate 1, so as to fill the support body hole h1. The support body film 21, for example, is a silicon oxide (SiO₂) film, and it is formed by CVD, for example. And as shown in FIGS. 5A and 5B, a support body 22 is formed from the support body film 21 by sequentially etching the support body film 21, the Si layers 13a and 13b, the SiGe layers 11a and 11b, and the Si-buffer layer (not shown) by using the photolithography technique and the etching technique. A groove h2 exposing the surface of the Si substrate 1 is also formed. In the etching step forming the groove h2, the etching may be stopped at the surface of the Si substrate 1, or a recess may be formed by over etching the Si substrate 1.

Next, in FIGS. 6A and 6B, the SiGe layers 11a and 11b are selectively etched and removed, by bringing an etching solution such as fluoronitric acid into contact with side surfaces of the Si layers 13a and 13b, and the SiGe layers 11a and 11b, respectively, interposing the groove h2 therebetween. A hollow portion 25 is formed between the Si layer 13a and the Si substrate 1. In a case when the fluoronitric acid is used as the etching solution, for example, it may only etch the SiGe layer, leaving the Si layer, as an etching rate of the SiGe layer is larger than that of the Si layer. Also, compared to the single crystal Si layer 13a, the Si layer 13b having the polycrystalline structure or the amorphous structure has a weaker bonding force between atoms and a larger etching rate. Therefore, in the etching step interposing the groove h2, not only the SiGe layers 11a and 11b, but also the Si layer 13b having the polycrystalline structure or the amorphous structure formed on the bird's beak are to be removed.

As a result, as shown in FIGS. 6A and 6B, a space 25a is provided between the side surface of the single crystal Si layer 13a and the support body 22. And an upper surface of the Si layer 13a is only supported by the support body 22. Next, as shown in FIG. 7A, a SiO₂ film 31 is formed to an inner wall of the hollow portion, by thermally oxidizing the Si substrate 1. At this point, as the side surface of the Si layer 13a is separated from the support body 22, an application of an external force to the side surface of the Si layer 13a from the support body 22 can be prevented, at an initial stage of the thermal oxidization (in other words, a stage that the space 25a remains sufficiently). This also enables to relieve compressive stress generated in the Si layer 13a, to the space 25a.

Next, using the CVD method and the like, the support body hole and the groove for introducing the fluoronitric acid are filled by depositing an insulating film on the entire surface of the Si substrate 1. The insulating film, for example, is a SiO₂ film and a silicon nitride (Si₃N₄) film. In a case when the hollow portion is not completely filled with the SiO₂ film 31, the filling of the hollow portion is supplemented by the formation of the insulating film. Next, as shown in FIG. 7B, an insulating film 33 covering the entire surface of the Si substrate 1 is planarized, for example, by chemical and mechanical polishing (CMP). Further, if necessary, the insulating film 33 is completely removed from the Si layer 13a, by wet etching the insulating film 33. Next, a gate insulating film is formed by thermally oxidizing the surface of the Si layer 13a. Furthermore, by the CVD method and the like, a polycrystalline silicon layer is formed on the Si layer formed with the gate insulating film. And the polycrystalline silicon layer is to be patterned by using the photolithography technique and the etching technique.

Accordingly, as shown in FIG. 7C, a gate electrode 43 is formed on a gate insulating film 41. Next, using the gate electrode 43 as a mask, a lightly doped drain (LDD) layer (not shown) made of a low concentration impurity introduction layer is formed on the Si layer 13a at the both sides of the gate electrode 43, by ion implanting an impurity such as As, P and B in the Si layer 13a. And by the CVD method and the like, the SiO₂ film, for example, is formed on the Si layer 13a formed with the LDD layer, and a side wall 45 is formed to a side wall of the gate electrode 43, by etching back the SiO₂ film, using an anisotropic etching such as a reactive ion etching (RIE). Further, using the gate electrode 43 and the side wall 45 as a mask, a source layer and a drain layer (not shown) made of a high concentration impurity introduction layer are formed to the Si layer 13a at the side of the side wall 45, by ion implanting the impurity such as As, P, and B in the Si layer 13a. Accordingly, a transistor having an SOI structure (in other words, an SOI transistor) is completed.

As the above, according to the first embodiment of the present invention, a support body adjacent portion in the Si layer 13 (in other words, Si layer 13b) can be formed in the polycrystalline structure or the amorphous structure. Therefore, when the hollow portion 25 is formed between the Si substrate 1 and the Si layer 13, not only the SiGe layer 11, but also the Si layer 13b having the polycrystalline structure or the amorphous structure can be etched, thereby enabling to provide the space 25a between the side surface of the Si layer 13a and the support body 22. When the SiO₂ film 31 is formed in the hollow portion 25, the stress of the Si layer 13a can be relieved, as the side surface of the Si layer 13a is separated from the support body 22. Therefore, desired transistor characteristics can be obtained.

According to the first embodiment, the Si substrate 1 corresponds to the “semiconductor substrate” of the invention. And the element isolation layer 3 corresponds to the “epitaxial growth stopper film” of the invention. Also, the SiGe layers 11a and 11b correspond to the “first semiconductor layer” of the invention, and the Si layers 13a and 13b correspond to the “second semiconductor layer” of the invention. Further, the support body hole hi corresponds to the “first groove” of the invention, and the groove h2 corresponds to the “second groove” of the invention. Furthermore, the SiO₂ film 31 corresponds to the “insulating layer” of the invention.

### Second Embodiment

In the above first embodiment, the element isolation layer 3 formed by the LOCOS process was used as the “epitaxial growth stopper film” of the invention. In such a structure, the forming step of the epitaxial growth stopper film and the step of element isolation can be performed at the same time, thereby enabling to reduce the number of manufacturing steps.

However, the “epitaxial growth stopper film” of the invention is not limited to the element isolation layer 3, and may be the SiO₂ film or the Si₃N₄ film formed on the Si substrate 1, other than the element isolation layer 3. As the both films have the amorphous structure, the semiconductor layer formed by the epitaxial growth process thereon becomes the polycrystalline structure or the amorphous structure. In the second embodiment, this point is to be explained.

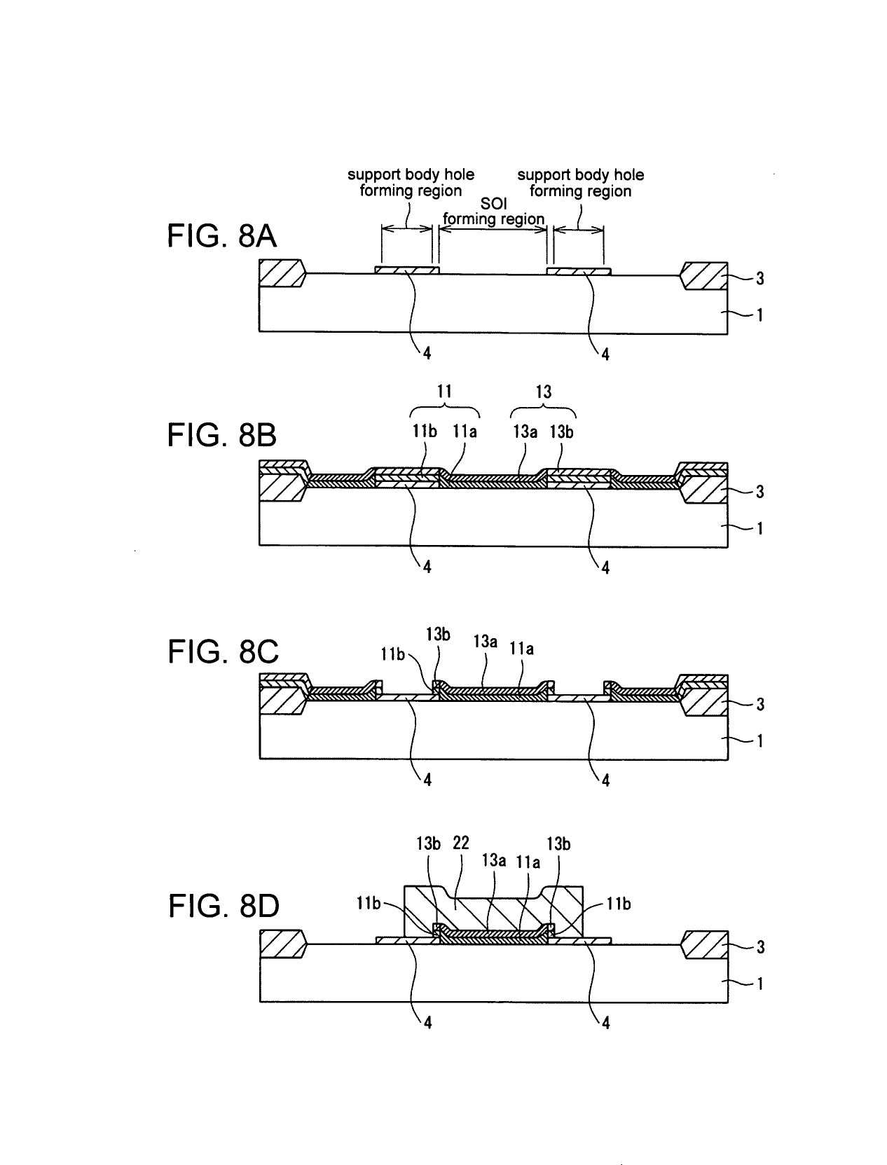

FIGS. 8A through 8D are sectional views showing a method for manufacturing a semiconductor device according to a second embodiment of the invention. In FIGS. 8A through 8D, portions having the same structure and function as those in FIGS. 1A through 7C described in the first embodiment are denoted by the same reference numerals, and descriptions thereof will be omitted. As shown in FIG. 8A, an element isolation layer 3 is formed on a Si substrate 1 by a LOCOS process. Next, a SiO₂ film 4 is formed on an entire surface of the Si substrate 1 by CVD method, for example. The SiO₂ film 4 is one example of an epitaxial growth stopper film, and a Si₃N₄ film may be used, instead of the SiO₂ film.

Next, by using a photolithography technique and an etching technique, the SiO₂ film 4 is partially etched to partially expose the surface of the Si substrate 1, from under the SiO₂ film 4. In this etching step, the SiO₂ film 4 is at least removed from the Si substrate 1 in a region that an SOI structure is formed (in other words, an SOI forming region), and the SiO₂ film 4 should be left on the Si substrate 1 in a region sandwiched between the SOI forming region and a region that a support body hole h1 is formed (in other words, a support body hole forming region).

The following steps are the same as the first embodiment. That is, as shown in FIG. 8B, a Si-buffer layer which is not shown is formed on the Si substrate 1. SiGe layers 11a and 11b are formed thereon, and Si layers 13a and 13b are formed thereon. As the Si-buffer layer, the SiGe layers 11a and 11b, and the Si layers 13a and 13b are formed by an epitaxial growth process, for example, a single crystal SiGe layer 11a is formed on the single crystal Si substrate 1. And the SiGe layer 11b having a polycrystalline structure or an amorphous structure is formed on the element isolation layer 3 and the SiO₂ film 4. Also, the single crystal Si layer 13a is formed on the single crystal SiGe layer 11a, and the Si layer 13b having the polycrystalline structure or the amorphous structure is formed on the SiGe layer 11b having the polycrystalline structure or the amorphous structure.

Next, as shown in FIG. 8C, using the photolithography technique and the etching technique, the Si layer 13b, the SiGe layer 11b and the Si-buffer layer (not shown) are partially etched. This enables to form the support body hole h1 penetrating through the Si layer 13b, the SiGe layer 11b and the Si-buffer layer, and having the SiO₂ film 4 as a bottom surface, at a region inside from an outer peripheral portion of the SiO₂ film 4.

Next, as in FIG. 8C, the support body film made of SiO₂ film and the like, for example, is formed on the entire surface of the Si substrate 1, so as to fill the support body hole h1. The support body film, the Si layers 13a and 13b, the SiGe layers 11a and 11b, and the Si-buffer layer (not shown) are partially etched by using the photolithography technique and the etching technique. And as shown in FIG. 8D, a support body 22 is formed from the support body film, and a groove h2 (see FIG. 5A) which exposes the surface of the Si substrate 1 is formed.

Next, the SiGe layers 11a and 11b are selectively etched and removed, by bringing an etching solution such as fluoronitric acid into contact with the side surfaces of the Si layers 13a and 13, and the SiGe layers 11a and 11b, respectively, interposing the groove h2 therebetween. A hollow portion is formed between the Si layer 13a and the Si substrate 1. In this etching step, not only the SiGe layers 11a and 11b, but also the Si layer 13b having the polycrystalline structure or the amorphous structure formed on the SiO₂ film 4 is to be removed.

As a result, as in the case of the first embodiment, a space 25a is provided between the side surface of the single crystal Si layer 13a and the support body 22. The upper surface of the Si layer 13a is only supported by the support body 22. Next, by thermally oxidizing the Si substrate 1, a SiO₂ film 31 is formed to an inner wall of the hollow portion. At this point, as the side surface of the Si layer 13a is separated from the support body 22, an application of an external force to the side surface of the Si layer 13a from the support body 22 can be prevented, at the initial stage of the thermal oxidation (in other words, a stage that the space 25a remains sufficiently). This also enables to relieve compressive stress generated in the Si layer 13a, to the space 25a

As described above, according to the second embodiment of the invention, a portion of the side surfaces of the Si layer 13 which comes in contact with the support body 22 (in other words, the Si layer 13b) can be formed in the polycrystalline structure or the amorphous structure. Therefore, when the hollow portion is formed between the Si substrate 1 and the Si layer 13, not only the SiGe layer 11, but also the Si layer 13b having the polycrystalline structure or the amorphous structure can be etched. This allows to provide the space 25a between the side surface of the the Si layer 13a and the support body 22. When the SiO₂ film 31 is formed in the hollow portion 25, the stress of the Si layer 13a can be relieved, as the side surface of the Si layer 13a is separated from the support body 22. Therefore, the desired transistor characteristics can be obtained.

Although the number of manufacturing steps may increase compared to the first embodiment, as the SiO₂ film 4 is made using the photolithography technique and the etching technique, its processing accuracy is higher than that of the element isolation layer 3 formed by the LOCOS process. Therefore, compared to the first embodiment, it is advantageous in miniaturization of semiconductor devices. In the second embodiment, the SiO₂ film 4 corresponds to the “epitaxial growth stopper film” of the invention. The other relations of correspondence are the same as those of the first embodiment.

In the above first and second embodiments, a case when the “semiconductor substrate” is a bulk silicon wafer, the “first semiconductor layer” is SiGe, and the “second semiconductor layer” is Si was explained. However, materials for the “semiconductor substrate”, the “first semiconductor layer” and the “second semiconductor layer” are not limited to these and for example, a combination selected from Si, Ge, SiGe, SiC, SiSn, PbS, GaAs, InP, GaP, GaN, ZnSe or the like may be used.

The entire disclosure of Japanese Patent Application No: 2007-008741, filed Jan. 18, 2007 is expressly incorporated by reference herein.

What is claimed is:

1. A method for manufacturing a semiconductor device, comprising:
partially forming an epitaxial growth stopper film on a single crystal semiconductor substrate;
sequentially depositing a first semiconductor layer and a second semiconductor layer on the semiconductor substrate by an epitaxial growth process;
forming a first groove penetrating through the second semiconductor layer and the first semiconductor layer on the semiconductor substrate, at a region inside from an outer peripheral portion of the epitaxial growth stopper film, by partially etching the second semiconductor layer and the first semiconductor layer;
forming a support body film on an entire surface of the semiconductor substrate, so as to fill the first groove and cover the second semiconductor layer;
forming a support body in a shape covering the second semiconductor layer from the first groove to an element region extending over the outer peripheral portion of the epitaxial growth stopper film, by partially etching the support body film;
forming a second groove exposing a side surface of the first semiconductor layer, by sequentially etching the second semiconductor layer and the first semiconductor layer exposing from under the support body;
forming a hollow portion between the semiconductor substrate and the second semiconductor layer, by selectively etching the first semiconductor layer interposing the second groove therebetween, under an etching condition that the first semiconductor layer is easier to etch than the second semiconductor layer; and
forming an insulating layer in the hollow portion.

2. A method for manufacturing a semiconductor device, comprising:
sequentially depositing a first semiconductor layer and a second semiconductor layer on a single crystal semiconductor substrate by an epitaxial growth process;
forming a first groove penetrating through the second semiconductor layer and the first semiconductor layer on the semiconductor substrate, by partially etching the second semiconductor layer and the first semiconductor layer;
forming a support body film on an entire surface of the semiconductor substrate, so as to fill the first groove and cover the second semiconductor layer;
forming a support body in a shape covering the second semiconductor layer from the first groove to an element region, by partially etching the support body film;
forming a second groove exposing a side surface of the first semiconductor layer, by sequentially etching the second semiconductor layer and the first semiconductor layer exposing from under the support body;
forming a hollow portion between the semiconductor substrate and the second semiconductor layer, by selectively etching the first semiconductor layer interposing the second groove therebetween, under an etching condition that the first semiconductor layer is easier to etch than the second semiconductor layer;
forming an insulating layer in the hollow portion; and
forming an epitaxial growth stopper film on the semiconductor substrate at a region sandwiched between a region forming the first groove and the element region before forming the first semiconductor layer, and the first semiconductor layer and the second semiconductor layer are also deposited on the epitaxial growth stopper film, in the step of forming the first semiconductor layer and the second semiconductor layer.

3. The method for manufacturing the semiconductor device, according to claim 1, wherein the epitaxial growth stopper film is an element isolation layer.
